(19) United States
(12) Patent Application Publication
(10) Pub. No.: US 2002/0125941 A1
(43) Pub. Date: Sep. 12, 2002

(54) High efficiency switching amplifiers

(76) Inventor: Tranh To Nguyen, Rohnert Park, CA (US)

Correspondence Address: TRANH NGUYEN, 1552 MAGNOLIA AVE., Rohnert Park, CA, 94928, US

(21) Appl. No.: 09/802,654

(22) Filed: Mar. 8, 2001

(51) Int. Cl. H03F 3/38; H03F 3/217

(52) U.S. Cl. 330/10; 330/251

(57) ABSTRACT

A family of switching amplifiers with reduced component count and lower current stresses on switches. The amplifiers have a power modulator comprising ground-referenced switches driving a tapped transformer which reduces current stresses on switches. A synchronous demodulator transforms modulated voltages back to audio signal. In one embodiment, the synchronous demodulator comprises switches in a H-bridge configuration selectively connecting the transformer to ground reference through a loudspeaker, driving it with bipolar voltages. Different embodiments using MOSFETs to implement the functions of a synchronous demodulator using bi-directional switches reduce total component count and increase the efficiency of the amplifiers. Timing control of the power modulator and the synchronous demodulator enables zero current switching of the power modulator.

### FIELD OF INVENTION

The present invention relates generally to power conversion, and specifically to switching power amplifiers.

### BACKGROUND OF THE INVENTION

Class-D switching amplifiers or digital amplifiers are well known subjects to electronics engineers. In automotive applications where the vehicle chassis forms a ground reference, amplifiers must operate from battery voltage which can get as low as 7 volts when the ambient air temperature is below freezing, even down to 3.5V when a starter is activated. As a result of low minimum battery voltages, high power switching amplifiers operating from battery voltage often require a boost converter, FIG. 1A, having a boost inductor, a main switch, a boost rectifier and a storage capacitor processing high levels of current. The current level that a high power amplifier has to deal with can be very high, in the tens of amperes for an output power of just about 50-100 watts. Conventional approaches using a boost converter and a class-D amplifier result in high losses in the MOSFET switches, and in the snubber networks, even in the so-called “lossless” snubbers. In such a lossless snubber, a current of 20 amperes through a Schottky rectifier would result in over 5 watts of heat dissipation in that rectifier. MOSFETs, often used in parallel, switching such a high current will dissipate similar heat quantities. Therefore the requirements of high efficiency, small size and low cost may not be easily met. These requirements apply even more relevantly to portable equipment operating from lower voltage battery such as public addressing megaphones or multimedia desktop computer, where space is at a premium. Of course, a DC voltage can be obtained from most AC voltage sources using a transformer and rectifiers. Indeed, in most conventional amplifiers, the power supply is a major, bulky and expensive component. Any technology that can increase energy efficiency of amplifiers would be beneficial.

For background, U.S. Pat. No. 5,963,086 provides a comprehensive list of patents of audio switching amplifiers of prior art and their deficiencies. U.S. Pat. No. 5,617,058 teaches a ternary switching amplifier using a tri-state power switch. U.S. Pat. No. 4,573,018 teaches a switching amplifier wherein the high frequency carrier voltage modulated by an audio input signal is passed through a transformer having a center-tapped secondary winding then rectified to recover the audio signal. Such an amplifier is not capable of driving a typical loudspeaker that is highly inductive, which requires bi-directional energy transfer from and to the DC power supply. U.S. Pat. No. 5,986,498 teaches similar rectification of the carrier voltage, therefore suffering from the same lack of bi-directional energy transfer capability, in addition to its limited bandwidth and high distortion due to its phase lag network, and difficulties to compensate for delays in transformers and their leakage inductances which have the tendency to slow down signals going through them.

Thus there is a need for a better approach to amplifiers for automotive and portable applications, or in general for battery-operated amplifiers, even for AC main operated amplifiers especially when the power demand is over 100 watts. Such power demand is common for some high power audio amplifiers and inverters.

### SUMMARY OF THE INVENTION

The invention provides a family of high power amplifiers operating primarily from low voltages. This family of amplifiers comprise a power modulator supplying modulated voltages to a transformer which changes the modulated voltages to higher levels. A synchronous demodulator reconstructs the audio signal from high level modulated voltages, driving a loudspeaker. The power modulator essentially combines switches carrying high currents in opposing directions into switches processing the difference of those high currents, resulting in very substantial reduction in conduction and switching losses, also losses in auxiliary circuits such as snubber networks. Furthermore, single-step power processing is applied to many embodiments of class-N amplifiers. Some of the transformers used in the various embodiments only have a tapped winding conducting only the difference of currents, therefore they are very small compared to a conventional multiple-winding transformer processing the same power, each winding conducting much higher current.

### OBJECTS AND ADVANTAGES

Accordingly, several objects and advantages of this invention are:

(a) to provide a method and apparatus to amplify an audio signal at high efficiency

(b) to provide a method and apparatus to minimize the size of switching amplifiers for battery-operated systems

(c) to provide a method and apparatus for minimizing component count in switching amplifiers

(d) to provide a method and apparatus for high efficiency switching amplifiers.

Further objects and advantages of this invention will become apparent from a consideration of the drawings and ensuing description.

### BRIEF DESCRIPTION OF THE DRAWINGS

FIG. 1 is a block diagram showing the major building blocks of the switching amplifiers of the present invention.

FIG. 2 is a schematic depicting a first embodiment of switching amplifiers of the present invention using push-pull power modulators, a center-tapped transformer, and a synchronized demodulator using conventional H-bridge in ternary mode.

FIG. 3 is a schematic illustrating the isolated version of the first embodiment.

FIG. 4 is a schematic illustrating an isolated switching amplifier using a half-bridge power modulator.

FIG. 5 is a schematic depicting an isolated switching amplifier using a full-bridge power modulator.

FIG. 6 is a schematic depicting a switching amplifier using a push-pull power modulator and a six-switch synchronous demodulator.

FIG. 7 is a schematic depicting a switching amplifier using a push-pull power modulator and a synchronous demodulator using four bi-directional switches in H-bridge configuration.

FIG. 8 is a schematic illustrating a switching amplifier using four MOSFETs in a modified H-bridge configuration with associated power modulator.

FIG. 9 is a schematic illustrating the easy of driving the MOSFETs used in FIG. 8.

FIG. 10 is a schematic illustrating an isolate switching amplifier using a modified H-bridge.

FIG. 11 is a schematic illustrating another isolated switching amplifier using modified H-bridge connected to two transformers.

FIG. 11B is a schematic illustrating yet another isolated switching amplifier using four ground-references MOSFETs and two isolated transformers.

FIG. 12 is a schematic illustrating an isolated switching amplifier using a modified H-bridge in conjunction with a half-bridge power modulator.

FIG. 13 is a schematic illustrating an isolated switching amplifier using a modified H-bridge in conjunction with a full-bridge power modulator.

### DESCRIPTION OF THE INVENTION

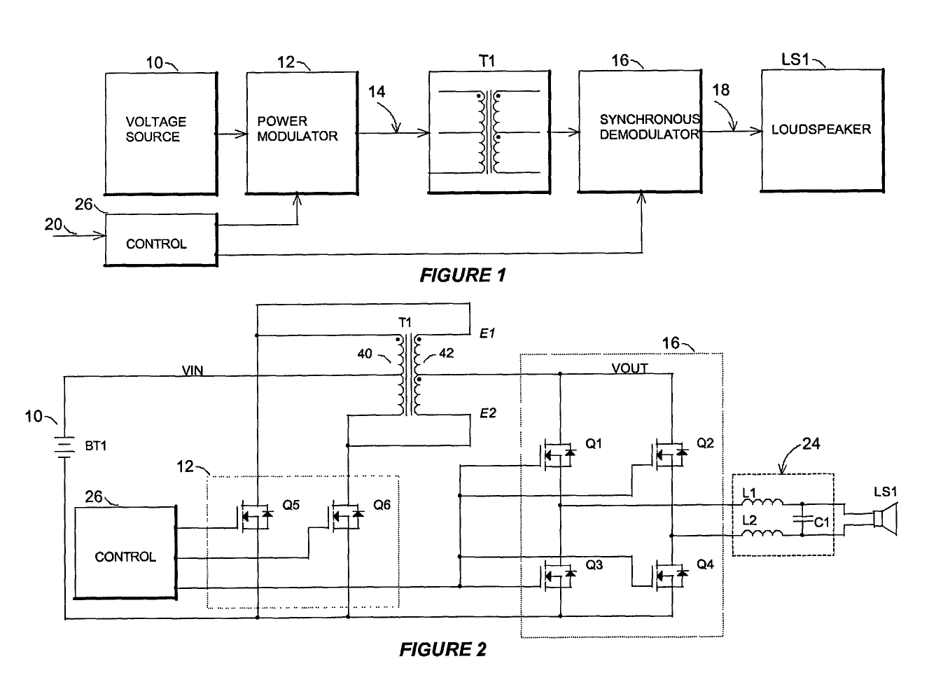

The invented family of class-N switching amplifiers in a general block diagram, FIG. 1, comprise a voltage source 10 supplying power to a power modulator 12 which produces pulse-width modulated (PWM) voltages 14 driving a transformer T1. A synchronous demodulator 16 reconstructs the signal from the PWM voltages 14 transmitted by the transformer T1 back to an amplified audio signal 18 driving a loudspeaker LS1. A controller 26 receiving an audio signal 20 as input, controls the operation of the power modulator 12 and the synchronous demodulator 16 by driving them with appropriate pulses. The power modulator 12 and its matched synchronous demodulator 16 in essence process the PWM voltages 14 at the same time

For clarification of definitions and terminologies, a modulator is typically an electronic circuit or device capable of providing pulses or waveforms whose at least one of the characteristics such as amplitude, frequency, phase, pulse duty ratio, energy etc . . . varies with an input or a modulating signal. A power modulator 12 puts out high energy signals typically by modulating or chopping a high voltage according to an input signal. A demodulator is a circuit or device that transforms a modulated signal into another signal of different characteristics, or more specifically a circuit or device that extracts the original modulating signal from a modulated signal. A synchronous demodulator is a demodulator that operates on a modulated signal using external timing signals which have some definite timing relationships with the modulated signal that the demodulator processes. In this specification both the modulator 12 and the synchronous demodulator 16 deal with signals that have essentially two states, low and high, thus they are deemed to process signals digitally.

In a first embodiment of the amplifier of this invention, as depicted in FIG. 2, a power modulator 12 comprising a push-pull pair of switches Q5-Q6 drives both the center-tapped primary winding 40 and the center-tapped secondary winding 42 of the transformer T1 by the end taps E1-E2 . The resulted boosted and pulsing output voltage VOUT is fed to a conventional H-bridge of switches Q1-Q4, however operated in ternary (or tri-state) mode as a synchronous demodulator 16, forming a switching amplifier. The operation of this switching (also called class-N) amplifier is as followed:

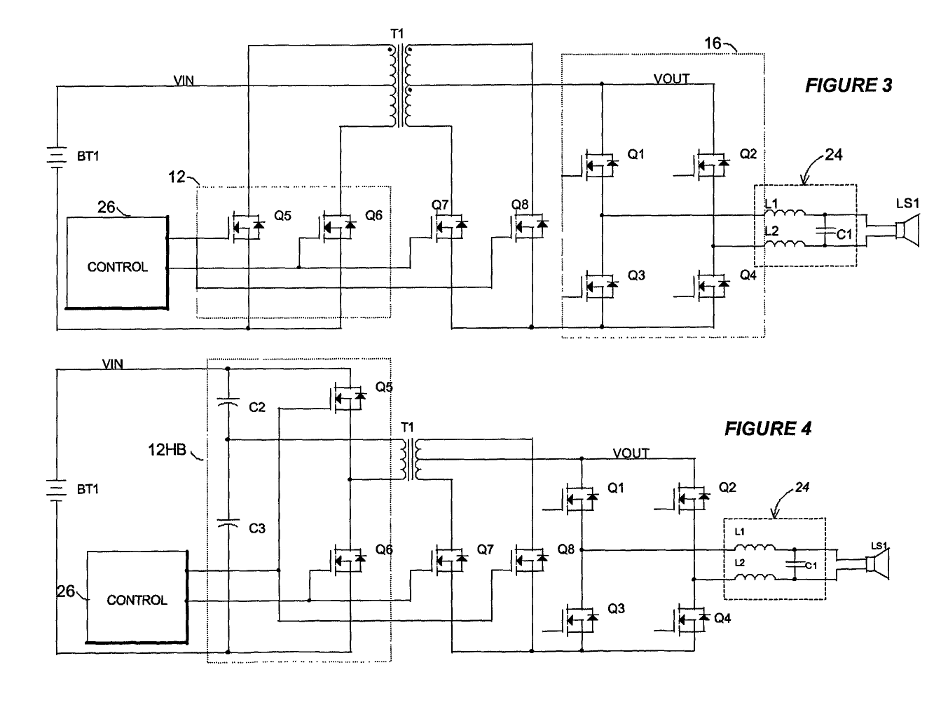

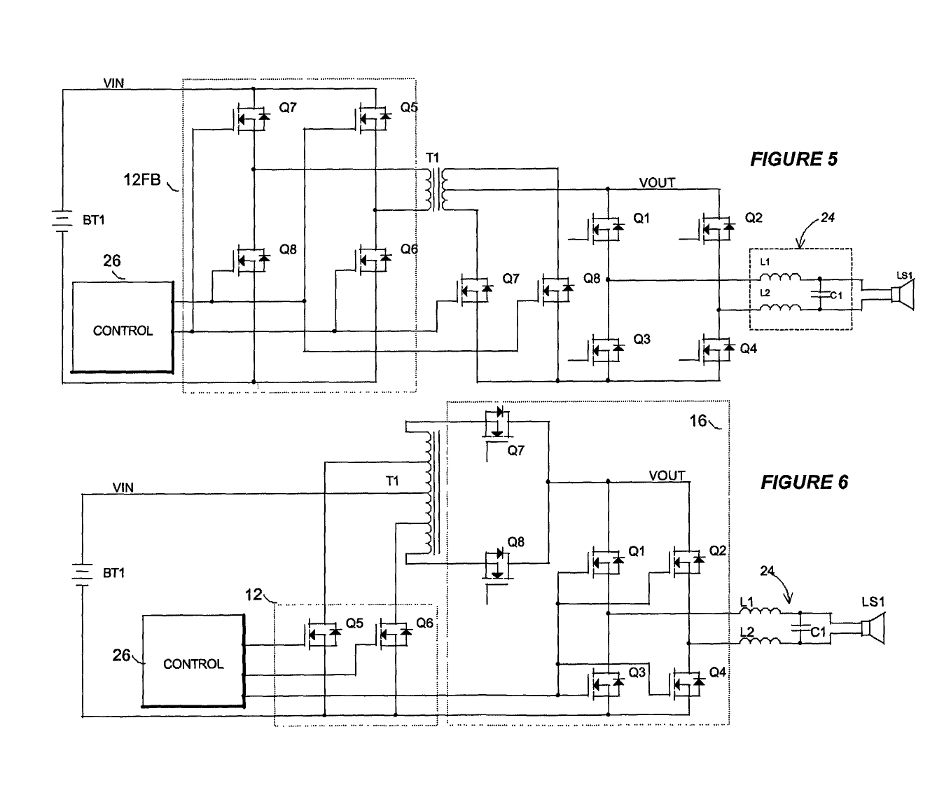

Whenever the MOSFET Q1 needs to be turned on by the controller 26 to drive the speaker LS1 in a positive direction, its opposite MOSFET Q4 is also turned on by the controller 26, as well as either MOSFET Q5 or Q6 in turn. During this period a voltage of Vin * n is applied to the LC output filter 24 in series with the loudspeaker LS1. When the MOSFET Q1 is turned off, its complementary MOSFET Q2 is turned on, and during the same period both MOSFET Q5 and Q6 are turned off, while the MOSFET Q4 continues to conduct. During this period a decreasing current continues to circulate through a load which comprises the LC output filter 24 and loudspeaker LS1 in series. Similarly, whenever the MOSFET Q2 needs to be turned on to drive the speaker LS1 in a negative direction, its opposite MOSFET Q3 is also turned on, as well as either MOSFET Q5 or Q6 in turn. When the MOSFET Q2 is turned off, its complementary MOSFET Q4 is turned on, and during the same period both MOSFETs Q5 and Q6 are turned off, while the MOSFET Q3 continues to conduct. Thus the H-bridge of switches Q1-Q4 can be controlled to apply a bipolar voltage to a load namely the loudspeaker LS1. This invented circuit arrangement reduces current stresses on the push-pull switches Q5-Q6 while allowing bi-directional energy transfer necessary for a switching amplifier driving a reactive load that most loudspeakers are. When isolation is required, i.e. the primary ground reference 30 is electrically isolated from the secondary ground reference 32, the circuit arrangement in FIG. 3 shows a preferred embodiment, where the driving mechanism of the switches are not shown in details for the clarity of the illustration. With this circuit arrangement as a starting point, the primary side of this class-N amplifier can be a half-bridge power modulator 12HB, FIG. 4, or a full H-bridge (also called full-bridge) power modulator 12FB commonly known in power conversion literature, FIG. 5.

Another embodiment of class-N amplifier is shown in FIG. 6. This embodiment uses a tapped transformer T1. It has lower current stresses for the push-pull switches Q5-Q6. Compared to the embodiment of FIG. 2, this circuit arrangement trades the lower losses in the switches Q5-Q6 and in the transformer T1 (also called a multiple-tap inductor) for added relatively low losses in the synchronous demodulator switches Q7-Q8, given very low on-resistance of low voltage MOSFETs nowadays. This embodiment of class-N amplifier works best in ternary mode, as already described above. It is relevant to point out that the MOSFETs Q7-Q8 are not used as synchronous rectifiers to increase their efficiency but as bi-directional switches to transfer energy in both directions. However, because of the unidirectional nature of the MOSFET Q1-Q2 and the ternary mode of operation of the H-bridge, regular MOSFETs Q7-Q8 instead of truly bi-directional switches can be used. To some extend, the MOSFETs Q7-Q8 are connected in opposite direction as the MOSFETs Q1-Q2, therefore in combination with them they form bi-directional switches. The H-bridge of switches Q1-Q4 here operates in ternary or tristate mode in conjunction with the bi-directional switches Q7-Q8 to form a synchronous demodulator, not in the binary mode of prior art class-D amplifiers. Indeed, it would not be possible to use an H-bridge operating in binary mode in this embodiment due to the switching nature of the voltage VOUT. Furthermore, an H-bridge is not the only possible implementation for class-N amplifiers.

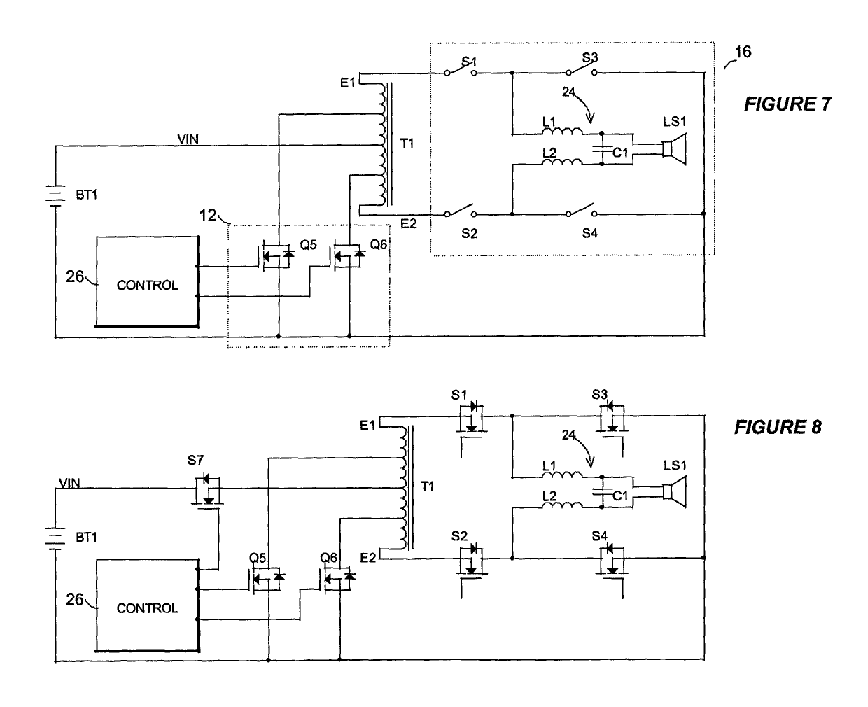

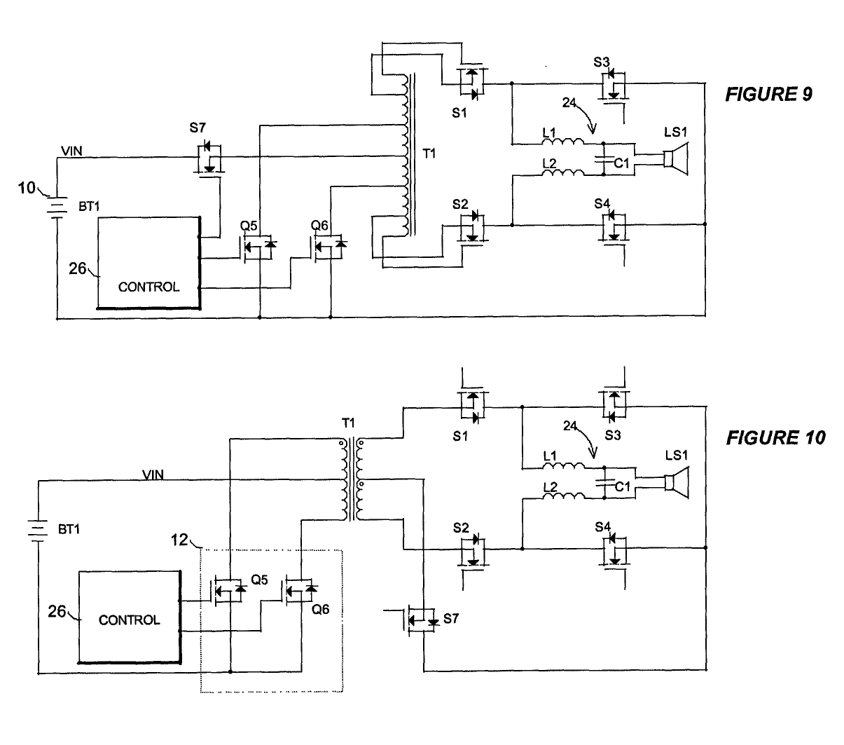

In a further improvement of the embodiment of class-N amplifier of FIG. 6, a simpler class-N amplifier is shown in FIG. 7, where the demodulator 16 comprising four switches S1-S4 forming a H-bridge connected directly to the end taps E1-E2 of the center-tapped transformer T1. This H-bridge can operate in binary mode or ternary mode, both with boosted voltages from the power modulator 12 comprising the ground-referenced switches Q5-Q6 and the multiple-tap transformer T1. If operated in ternary mode, one of its possible implementations use regular MOSFETs connected in opposition forming a modified H-bridge, with the addition of the switch Q7 blocking when both switches Q5-Q6 are blocking, during which time both switches Q3-Q4 conduct, as shown in FIG. 8. The transformer T1 in this case can have slight flux imbalance due to possible unequal pulse widths driving it at each of its two sides. This flux imbalance is minor due to the low voltage of the battery BT1, and it can be compensated by core a reset circuit for each side of the transformer T1, or by a large cross section for the transformer T1 to keep its flux density below its saturation flux level. This implementation of H-bridge is particularly simple to drive due to ground-referenced switches S3-S4-Q5-Q6 and transformer-referenced switches S1-S2, which can be driven using two more taps on the transformer T1, FIG. 9. Thus this implementation of class-N amplifier does not need a conventional H-bridge driver, therefore it may be the most cost-effective embodiment. It is essential to point out that the switches S1-S4 of this embodiment conduct current in both directions, due the inductive nature of most loudspeakers, so do the ground-referenced switches Q5-Q6, although all switches can be implemented with MOSFETs which have built-in unidirectional rectifiers. Again, the ground referenced switches Q5-Q6 conduct only a fraction of the battery current, thus their low losses. Therefore it is projected that a class-N amplifier according to this embodiment may have the highest overall energy efficiency of all switching amplifiers while having the fewest number of parts.

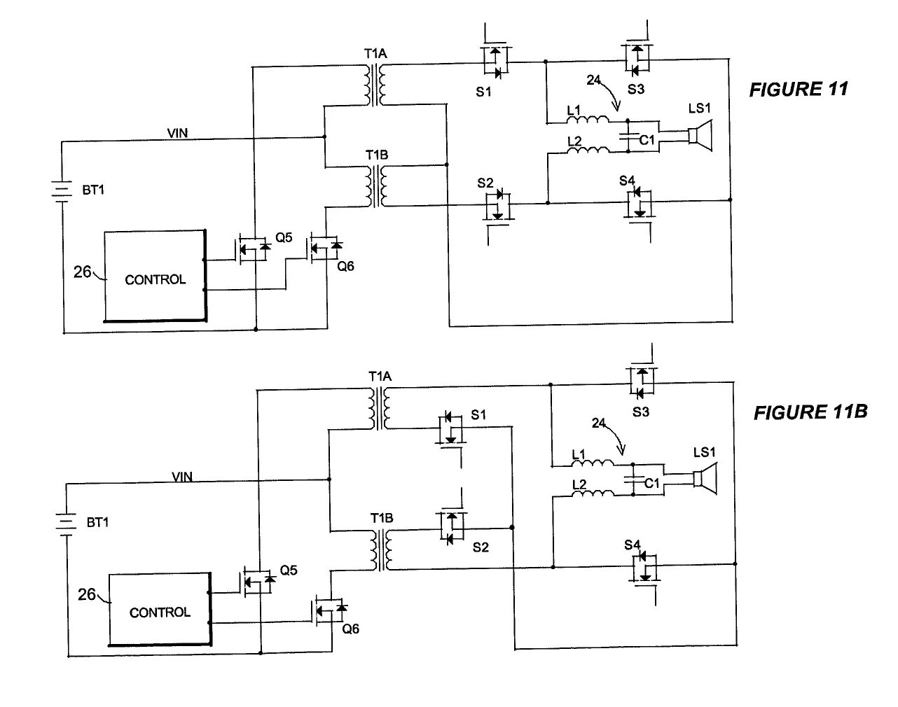

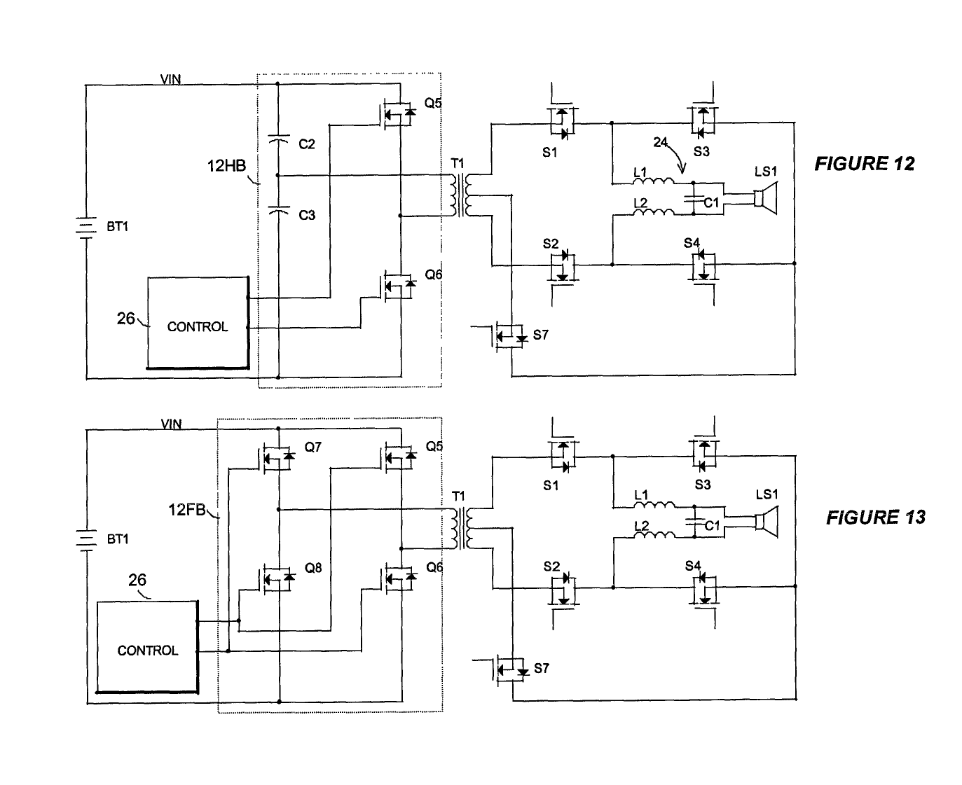

When electrical isolation between the voltage source and the load-a loudspeaker-is needed, a transformer T1 with a primary winding and a center-tapped secondary winding can be used with the modified H-bridge of FIG. 9, as shown in FIG. 10, where the switch S7 is now on the secondary side of the transformer T1. This switch Q7 is blocking when both switches Q3-Q4 are conducting while the switches Q5-Q6 of the power modulator 12 are both OFF. This embodiment works best in ternary mode because of inherent limitation in the maximum duty ratio of the pulses. Another embodiment of isolated class-N amplifier, FIG. 11, uses a synchronous demodulator 16 consisting of the modified H-bridge switches S1-S4 by using two identical transformers T1A-T1B to do away with the need for the switch Q7 of FIG. 10. Other variations of embodiments using modified H-bridge directly connected to a center-tapped secondary 42 of an isolation transformer T1 comprise a half-bridge power modulator 12HB, FIG. 12, and a full-bridge power modulator 12FB, FIG. 13, on the primary side of the transformer T1. A proper implementation of these transformer-isolated embodiments will have to address the issue of transformer flux imbalance in similar fashion as in previous paragraph. These embodiments do not have the property of reduced switch current. On the other hand they are mostly used in high voltage application, therefore high switch current is often not an issue.

In all the above embodiments, the details of the controller 26 were not mentioned. The controller 26 is subject of a co-pending patent application teaching a one-cycle response PWM controller by the same applicant. That controller 26 is a non-linear controller and it is outside the scope of this patent application. A major difference between this invention and prior art of U.S. Pat. Nos. 4,573,018, 5,986,498, and 4,980,649 is the capability of bi-directional energy transfer of the synchronous demodulator 16, so that the class-N amplifiers of this invention can drive an inductive loudspeaker, or even a capacitive one. A second major difference with prior art is in the direct controlling of the operation of the synchronous demodulator 16 by the controller 26. This direct control of the synchronous demodulator 16 can be extremely precise in terms of timing, limited only by the speed of logic circuits used, therefore a class-N amplifier can achieve very low distortion and very high efficiency. As discussed earlier, the configurations and the operation of the power modulator 12 contributes significantly to low losses in the switches and in the transformer T1, but because of accurate timing provided by the controller 26, any delay in the transformer T1 and switches can be compensated for by the controller 26.

The fact that the controller 26 provides timing signals to both the power modulator 12 and the synchronous demodulator 16 leads to another major advantage of this invention.

Referring to FIG. 2, by having the controller 26 turning on the switches Q5-Q6 of the power modulator 12 before turning on the switches Q1-Q4 of the synchronous demodulator 16, and vice versa by turning off the switches Q5-Q6 of the power modulator 12 after turning off appropriate switch Q1 or Q2 of the synchronous demodulator 16, zero current switching (ZCS) of the power modulator 12 can be achieved. Indeed, still referring to FIG. 2 as an example, when both switches Q1-Q2 of the synchronous demodulator 16 are off while both switches Q3-Q4 are on, no current can flow out of the center tap of the transformer T1, therefore either switch Q5 or Q6 of the power modulator 12 can be turned on or turned off in ZCS. Thus the switching losses of the switches Q5-Q6 which normally carry heavy currents are virtually zero. Indeed, all the different power modulators 12 of the class-N amplifiers if this invention can be controlled to operate in ZCS, due to the simplicity of timing control of the power modulator 12 and the synchronous demodulator 16 by the controller 26. With ZCS, snubbers are not necessary. ZCS behavior is very difficult to implement in prior art circuits which did not teach it at all, without increasing further the distortion of the audio signal 18 (FIG. 1) driving the loudspeaker LS1.

From the description above, a number of advantages of the invented circuit arrangements become evident:

(a) current stress on switches is significantly lower in non-isolated class-N amplifiers,

(b) the transformer is significantly smaller than a conventional push-pull transformer,

(c) energy efficiency is much higher due reduced conduction losses in all components and virtually zero switching losses in switches that carry high currents,

(d) low component count compared to conventional class-D amplifier and its independent power supply.

### SUMMARY, RAMIFICATION AND SCOPE

Accordingly the reader would see that the invented circuit arrangements are significantly advantageous in automotive or battery-operated electronics, as well as in cases of power from AC main, when compared to well known class-D or other switching amplifiers.

When isolation is required between primary and secondary circuits, class-N amplifiers still present advantages in energy efficiency and component count, therefore higher reliability, smaller size and weigh, and lower cost. Such isolated amplifiers can be used anywhere there is an AC or DC power source, whether it is low voltage or high voltage.

While the preferred embodiment of the present invention has been shown and described herein, it will be obvious that such embodiment is provided by way of example only. Numerous variations, changes, and substitutions will occur to those of skill in the art without departing from the invention herein. Thus the scope of the invention should be determined by the appended claims and their legal equivalents, rather than by the example given.

I claim:

1. A high efficiency switching amplifier for digitally processing electric power from a DC supply thereof to a loudspeaker, said switching amplifier comprising:
a voltage source for supplying a DC voltage,
a power modulator for transforming said DC voltage into modulated voltages,
a transformer for changing the amplitudes of said modulated voltages,
a synchronous demodulator for reconstructing said modulated voltages back to audio signal driving a loudspeaker,
a controller for receiving an audio signal to produce digital signals controlling the operation of said power modulator and said synchronous demodulator,
wherein said controller controlling the timing of said power modulator to operate it in zero current switching.

2. A high efficiency switching amplifier comprising:
a transformer having a primary winding with a first terminal, a second terminal, a third terminal which is a primary center tap, and a secondary winding with a fourth terminal, a fifth terminal, and a sixth terminal which is a secondary center tap,
a power modulator comprising a first switch for selectively connecting said first and fourth terminals of said transformer to a ground reference, and a second switch for selectively connecting said second and fifth terminal of said transformer to said ground reference,
a voltage source connected between said third terminal and said ground reference,
a synchronous demodulator comprising four switches in a H-bridge configuration for selectively connecting said sixth terminal of said transformer to said ground reference through a load,
a controller for receiving an audio signal to produce digital signals controlling the operation of said power modulator and said synchronous demodulator,
wherein said four switches of said H-bridge provide a bipolar signal to said load connected across said H-bridge, and wherein said controller controlling the timing of said power modulator to operate it in zero current switching.

3. A high efficiency switching amplifier comprising:
a transformer having a primary winding and a secondary winding having a first terminal, a second terminal, a third terminal which is a center tap, a voltage source connected to said primary winding of said transformer,
a power modulator for selectively connecting said primary winding of said transformer to a primary ground reference,
a synchronous demodulator comprising first and second switches for selectively connecting said first and second terminals of said transformer to a secondary ground reference, and four switches in a H-bridge configuration for selectively connecting said center tap of said transformer to said secondary ground reference via a load,
a controller for receiving an audio signal to produce digital signals controlling the operation of said power modulator and said synchronous demodulator,
wherein said four switches of said H-bridge provide a bipolar signal to said load connected across said H-bridge, and said wherein controller controlling the timing of said power modulator and said first and second switches of said synchronous demodulator to operate them in zero current switching.

4. The switching amplifier of claim 3 wherein said power modulator is a push-pull power switch.

5. The switching amplifier of claim 3 wherein said power modulator is a half-bridge power switch.

6. The switching amplifier of claim 3 wherein said power modulator is a full-bridge power switch.

7. A high efficiency switching amplifier comprising:
a transformer having a multiple-tap winding with a first terminal, a second terminal, a third terminal which is a center tap, a fourth terminal, and a fifth terminal,
a power modulator comprising first and second switches for selectively connecting said first and second terminals of said transformer to a ground reference,
a voltage source connected between said third terminal of said transformer and said ground reference,
a synchronous demodulator comprising a first and a second bi-directional switches having a common connection node and each connected in series with said fourth and fifth terminals of said transformer, and four switches in a H-bridge configuration for selectively connecting said common connection node of said first and second bi-directional switches to ground reference through a load,
a controller for receiving an audio signal to produce digital signals controlling the operation of said power modulator and said synchronous demodulator,
wherein said controller controlling the timing of said power modulator to operate it in zero current switching.

8. The switching amplifier of claim 7 wherein said synchronous demodulator comprises four bi-directional switches in a H-bridge configuration for selectively connecting said fourth and fifth terminals of said transformer to ground reference through a load.

9. The switching amplifier of claim 7 wherein said power modulator comprises additionally a third switch in series with said center tap of said transformer and wherein said four switches of said H-bridge are MOSFETs.

10. The switching amplifier of claim 8 wherein said transformer is an isolating transformer having a primary winding and a secondary winding, said secondary winding having a center tap.

11. The switching amplifier of claim 10 wherein said synchronous demodulator comprises four MOSFETs in a H-bridge configuration and a fifth MOSFET connected in series with said center tap.

12. The switching amplifier of claim 11 wherein said power modulator is a half-bridge power modulator.

13. The switching amplifier of claim 11 wherein said power modulator is a full-bridge power modulator.

14. The switching amplifier of claim 10 wherein said isolating transformer is split into two isolating transformers having windings connected in series.

15. The switching amplifier of claim 14 wherein two of said four switches in a H-bridge configuration are relocated to be connected to said ground reference.

16. The switching amplifier of claim 15 wherein said four switches are ground-referenced MOSFETs.

17. A high efficiency switching amplifier for digitally processing electric power from a DC supply to drive a loudspeaker isolated from the DC supply, said switching amplifier comprising:
a voltage source for supplying a DC voltage,
a power modulator for transforming said DC voltage into modulated voltages,
two transformers for changing the amplitudes of said modulated voltages, said two transformers having each a primary winding and a secondary winding, said two primary windings being connected in series,
a synchronous demodulator for reconstructing said modulated voltages back to audio signal driving a loudspeaker, said demodulator comprising four bi-directional switches selectively connecting said two secondary windings to a secondary ground reference isolated from said voltage source, through said loudspeaker,
a controller for receiving an audio signal to produce digital signals controlling the operation of said power modulator and said synchronous demodulator,
wherein said controller controlling the timing of said power modulator to operate it in zero current switching.

18. The switching amplifier of claim 17 wherein said four bi-directional switches of said synchronous demodulator are transistors.

19. The switching amplifier of claim 17 wherein said four bi-directional switches of said synchronous demodulator are four MOSFETs.

20. A method for reducing switching losses of a switching amplifier having a power modulator, a transformer, a synchronous demodulator, and a controller, said method comprising adaptively sending timing signals to said power modulator, and after predetermined delays, sending timing signals to said synchronous demodulator, wherein said predetermined delays cause said power modulator to operate in zero current switching.
